(19) United States
(12) Patent Application Publication
(10) Pub. No.: US 2025/0204228 A1
(43) Pub. Date: Jun. 19, 2025

(54) DISPLAY APPARATUS HAVING LIGHT-EMITTING DEVICES

(71) Applicant: LG Display Co., Ltd., Seoul (KR)

(72) Inventors: Cheol Hwan LEE, Paju-si (KR); Chan Wook CHOI, Paju-si (KR); Yeon Suk KANG, Paju-si (KR)

(21) Appl. No.: 18/978,272

(22) Filed: Dec. 12, 2024

(30) Foreign Application Priority Data
Dec. 14, 2023 (KR) 10-2023-0181770

(51) Int. Cl. H10K 59/80; H10K 59/38

(52) U.S. Cl. CPC H10K 59/879; H10K 59/38

(57) ABSTRACT

A display apparatus including light-emitting devices is provided. The light-emitting devices can be disposed on emission areas of a device substrate. Color filters can be disposed on the emission areas. Lens structure can be disposed between the light-emitting device and the color filter of each emission area. Each of the lens structure can include at least three layers. Each of boundaries between layers within each lens structure can have as a convex shape toward the device substrate. Thus, in the display apparatus, efficiency in concentrating light can be improved.

### CROSS-REFERENCE TO RELATED APPLICATIONS

This application claims the benefit of Korean Patent Application No. 10-2023-0181770, filed on Dec. 14, 2023, which is hereby incorporated by reference as if fully set forth herein.

### BACKGROUND

### Technical Field

The present disclosure relates to a display apparatus in which a light-emitting device is disposed on each emission area.

### Description of the Related Art

Generally, a display apparatus provides an image to a user. For example, the display apparatus can include a plurality of light-emitting devices. Each of the light-emitting devices can emit light displaying a specific color. For example, each of the light-emitting devices can include a light-emitting unit disposed between a first electrode and a second electrode.

The image realized by the display apparatus can include various colors. For example, the display apparatus can include color filters disposed on the light-emitting devices. Each of the color filters can include a different material from adjacent color filter. For example, the color filters can include a red color filter displaying a red color, a green color filter displaying a green color, and a blue color filter displaying a blue color.

### BRIEF SUMMARY

The light passing through each color filter can be concentrated by a lens. For example, lenses having a hemispheric shape can be disposed on the color filters. However, in the display apparatus, the size of each lens can be reduced as resolution increases. Thus, the inventors of the present disclosure have appreciated that in the display apparatus, a process of forming lenses can become complicated, and the uniformity of the lenses can decrease. Further, in the display apparatus, luminance deviation can occur due to differences in the shapes of the lenses. Therefore, in the display apparatus, the quality of the image can be deteriorated. Accordingly, the inventors of the present disclosure have provided various embodiments of a display apparatus that substantially obviates one or more problems due to limitations and disadvantages of the related art.

Various embodiments of the present disclosure provide a display apparatus capable of simplifying a process of forming the lens structure for concentrating the light emitted from each light-emitting device.

Various embodiments of the present disclosure provide a display apparatus capable of improving the uniformity of the lens structure disposed on the emission areas.

Additional advantages, benefits, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these technical benefits and other advantages and in accordance with the purpose of the present disclosure, as embodied and broadly described herein, there is provided a display apparatus comprising a device substrate. A light-emitting device and an encapsulation structure are disposed on the device substrate. The light-emitting device is disposed on the emission area of the device substrate. The encapsulation structure covers the light-emitting device. A lens structure and a barrier are disposed on the encapsulation structure. The lens structure includes a first lens insulating layer, a second lens insulating layer and a lens passivation layer, which are sequentially stacked on the encapsulation structure of the emission area. The barrier is in contact with a side of the lens structure. A color filter is disposed on the lens structure. The color filter overlaps the emission area. The second lens insulating layer has a larger refractive index than the first lens insulating layer. The lens passivation layer has a larger refractive index than the second lens insulating layer. An upper surface of the first lens insulating layer and an upper surface of the second lens insulating layer toward the color filter have a concave shape toward the device substrate.

The upper surface of the second lens insulating layer can have a same curvature as the upper surface of the first lens insulating layer.

The barrier can include a material having a larger reflectance than the first lens insulating layer, the second lens insulating layer and the lens passivation layer.

The barrier can include a metal.

The lens passivation layer can include a material harder than the first lens insulating layer and the second lens insulating layer.

The first lens insulating layer and the second lens insulating layer can include an organic insulating material. The lens passivation layer can include an inorganic insulating material.

An upper surface of lens passivation layer toward the color filter can have a concave shape toward the device substrate.

An upper end of the barrier toward the color filter can be spaced apart from the color filter. The lens passivation layer can extend between the upper end of the barrier and the color filter.

The refractive index of the color filter can be larger than the refractive index of the lens passivation layer.

The refractive index of the color filter can be smaller than the refractive index of the lens passivation layer.

The upper surface of the lens passivation layer can have a same curvature as the upper surface of the second lens insulating layer.

A thickness of the first lens insulating layer disposed in each emission area can gradually increase from a central area of the corresponding emission area toward the barrier.

A boundary between the first lens insulating layer and the second lens insulating layer disposed in each emission area can function as a lens.

A boundary between the second lens insulating layer and the lens passivation layer disposed in each emission area can function as a lens.

In another embodiment, there is provided a display apparatus comprising a device substrate. A first light-emitting device is disposed on a first emission area of the device substrate. An encapsulation structure is disposed on the first light-emitting device. The encapsulation structure extends outward of the first emission area. A first lens structure and a first barrier are disposed on the encapsulation structure. The first lens structure includes at least three layers stacked on the encapsulation structure of the first emission area. The first barrier is in contact with a side of the first lens structure. A first color filter is disposed on the first lens structure. The first color filter overlaps the first emission area. Each layer of the first lens structure has a larger refractive index as it moves away from the encapsulation structure. Each of boundaries between the layers within the first lens structure has a convex shape toward the device substrate.

A vertical distance between the device substrate and each boundary can increase from a central area of the emission area to the first barrier.

A second light-emitting device can be disposed between a second emission area of the device substrate and the encapsulation structure. A second lens structure can be disposed on the encapsulation structure of the second emission area. The second lens structure can have a structure in which at least three layers are stacked. A second barrier contacting a side of the second lens structure can be disposed on the encapsulation structure. A second color filter can be disposed on the second lens structure. The second color filter can overlap the second emission area. The first barrier and the second barrier can extend in a first direction. The second emission area can be disposed side by side with the first emission area in the first direction. The second color filter can include a same material as the first color filter.

The second barrier can be spaced apart from the first barrier between the first emission area and the second emission area.

A third barrier can be disposed between the first emission area and the second emission area. The third barrier can extend in a second direction perpendicular to the first direction.

A third light-emitting device can be disposed between a third emission area of the device substrate and the encapsulation structure. A third lens structure can include at least three layers stacked on the encapsulation structure of the third emission area. A fourth barrier can be disposed on the encapsulation structure, the fourth barrier is in contact with a side of the third lens structure. A third color filter can be disposed on the third lens structure, the third color filter can overlap with the third emission area. Each layer of the third lens structure has a larger refractive index as it moves away from the encapsulation structure. Each of boundaries between the layers within the third lens structure has a convex shape toward the device substrate.

In yet another embodiment, there is provided a display apparatus comprising a device substrate. A light-emitting device is disposed on a plurality of emission areas of a device substrate. An encapsulation structure is disposed on the device substrate. The encapsulation structure covers the light-emitting device. Each of a plurality of lens structures includes a plurality of layers stacked on the encapsulation structure of the plurality of emission areas. A plurality of color filters are disposed on the plurality of lens structures, each of the plurality of color filters overlapping with each of the plurality of emission areas. Each layer of each of the plurality of lens structures has a larger refractive index as it moves away from the encapsulation structure. Each of boundaries between the layers within each of the plurality of lens structures has a convex shape toward the device substrate.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a sub-pixel in the display apparatus according to the embodiment of the present disclosure;

FIG. 3 is an enlarged view of K1 region in FIG. 1;

FIG. 4 is a view taken along I-I′ of FIG. 3;

FIG. 5 is an enlarged view of K2 region in FIG. 4;

FIGS. 6 to 8 are views sequentially showing a method of forming the display apparatus according to the embodiment of the present disclosure; and

FIGS. 9 to 13 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, the same or extremely similar elements can be designated by the same reference numerals throughout the specification and in the drawings, the lengths and thickness of layers and regions can be exaggerated for convenience. It will be understood that, when a first clement is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

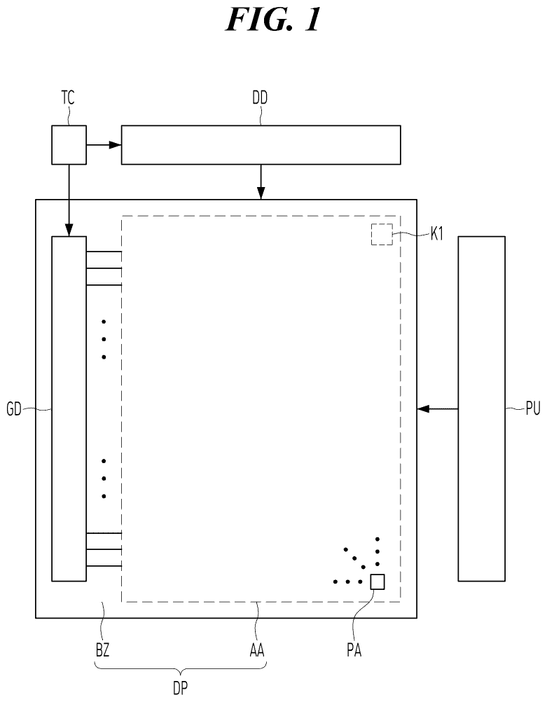

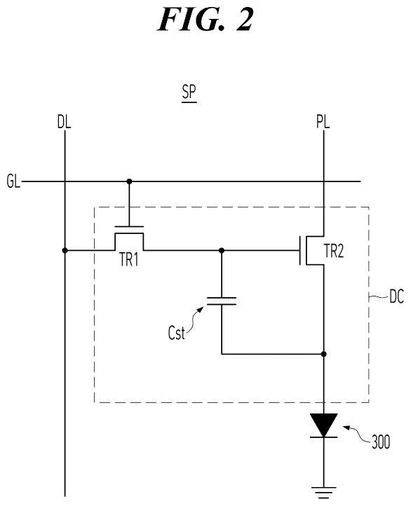

FIG. 1 is a view schematically showing a display apparatus according to an embodiment of the present disclosure. FIG. 2 is a view showing a circuit of a sub-pixel in the display apparatus according to the embodiment of the present disclosure.

Referring to FIGS. 1 and 2, the display apparatus according to the embodiment of the present disclosure can include a display panel DP. The display panel DP can generate an image provided to a user. For example, the display panel DP can include a plurality of pixel areas PA. Various signals can be provided in each pixel area PA through signal wirings GL, DL and PL. For example, the signal wirings GL, DL and PL can include gate lines GL applying a gate signal, data lines DL applying a data signal, and power voltage supply lines PL supplying a power voltage.

The gate lines GL can be electrically connected to a gate driver GD. The data lines DL can be electrically connected to a data driver DD. The power voltage supply lines PL can be electrically connected to a power unit PU. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC.

The display panel DP can include the active area AA in which the pixel areas PA are disposed, and a bezel area BZ (also referred to as an edge area) disposed outside the active area AA. The pixel areas PA do not overlap the bezel area BZ. For example, the active area AA can be surrounded by the bezel area BZ. The gate driver GD, the data driver DD, the power unit PU and the timing controller TC can be disposed outside the active area AA. For example, each of the signal wirings GL, DL and PL can include a region disposed on the bezel area BZ.

At least one of the gate driver GD, the data driver DD, the power unit PU and the timing controller TC can be disposed on the bezel area BZ. For example, the display apparatus according to the embodiment of the present disclosure can be a GIP (Gate In Panel) type display apparatus in which the gate driver GD is formed on the bezel area BZ of the display panel DP.

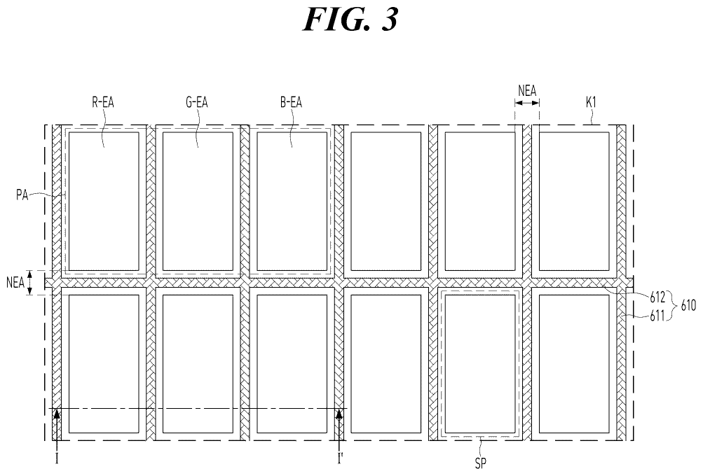

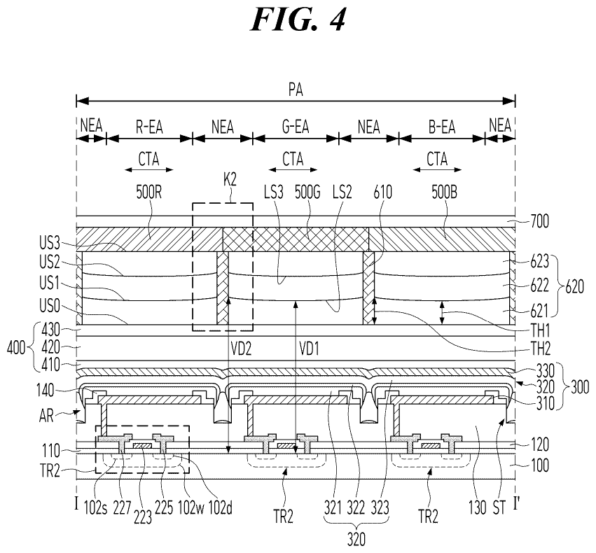

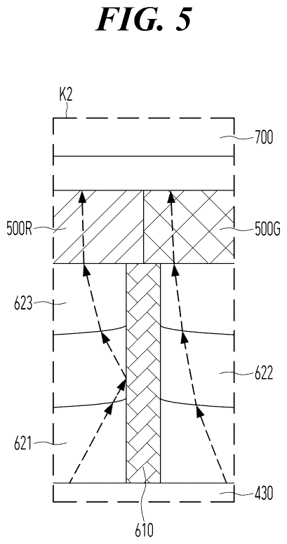

FIG. 3 is an enlarged view of KI region in FIG. 1. FIG. 4 is a view taken along I-I′ of FIG. 3. FIG. 5 is an enlarged view of K2 region in FIG. 4.

Referring to FIGS. 2 to 4, in the display apparatus according to the embodiment of the present disclosure, each of the pixel areas PA can include a plurality of sub-pixels SP. Each of the sub-pixels SP can realize a specific color. For example, a light-emitting device 300 can be disposed in each sub-pixel SP. The light-emitting device 300 of each sub-pixel SP can emit light displaying a specific color. For example, the light-emitting device 300 of each sub-pixel SP can include a first electrode 310 and a second electrode 330, and a light-emitting unit 320 disposed between the first electrode 310 and the second electrode 330.

The first electrode 310 can include a conductive material. The first electrode 310 can include a material having a high reflectance. For example, the first electrode 310 can be a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting unit 320 can generate light having luminance corresponding to a voltage difference between the first electrode 310 and the second electrode 330. For example, the light-emitting unit 320 can include an emission material layer (EML). The emission material layer (EML) can include an emission material. The emission material can include an organic material, an inorganic material or a hybrid material. For example, the display apparatus according to the embodiment of the present disclosure can be an organic light-emitting display apparatus including an organic emission material.

A plurality of emission material layers (EML) can be disposed in the light-emitting unit 320. For example, the light-emitting unit 320 can include a first emission stack 321, a second emission stack 323, and a charge generation layer 322. Each of the first emission stack 321 and the second emission stack 322 can include at least one emission material layer (EML). Each of the first emission stack 321 and the second emission stack 323 can emit light. For example, a charge generation layer 322 can be disposed between the first emission stack 321 and the second emission stack 323. The charge generation layer 322 can supply holes or electrons to the first emission stack 321 and the second emission stack 323.

Light generated by the second emission stack 323 can display a different color from light generated by the first emission stack 321. For example, the emission material layer (EML) of the second emission stack 323 can include a different material from the emission material layer (EML) of the first emission stack 321. A color represented by light generated by the light-emitting unit 320 can be a color represented by overlapping the light generated by the first emission stack 321 and the light generated by the second emission stack 323.

Each of the first emission stack 321 and the second emission stack 323 can further include at least one functional layer to smoothly supply holes or electrons. For example, each of the first emission stack 321 and the second emission stack 323 can include at least one of a hole injection layer (HIL), a hole transport layer (HTL), an electron transport layer (ETL) and an electron injection layer (EIL). Thus, in the display apparatus according to the embodiment of the present disclosure, efficiency of the light-emitting unit 320 can be improved.

The second electrode 330 can include a conductive material. The second electrode 330 can include a different material from the first electrode 310. A transmittance of the second electrode 330 can be higher than a transmittance of the first electrode 310. For example, the second electrode 330 can be a transparent electrode made of a transparent conductive material, such as ITO and IZO, or a translucent electrode in which metals such as Ag and Mg are thinly formed. Thus, in the display apparatus according to the embodiment of the present disclosure, the light generated by the light-emitting unit 320 can be emitted outside through the second electrode 330.

The light-emitting device 300 of each sub-pixel SP can be controlled independently from the light-emitting device 300 of adjacent sub-pixel SP. For example, a driving circuit DC electrically connected to the light-emitting device 300 can be disposed in each sub-pixel SP. The driving circuit DC of each sub-pixel SP can electrically connected to the signal wirings GL, DL and PL. For example, the driving circuit DC of each sub-pixel SP can be connected to one of the gate lines GL, one of the data lines DL and one of the power voltage supply lines PL. The driving circuit DC of each sub-pixel SP can supply a driving current corresponding to the data signal to the light-emitting device 300 of the corresponding sub-pixel SP according to the gate signal for one frame. For example, the driving circuit DC of each sub-pixel SP can include a first thin film transistor TRI, a second thin film transistor TR2 and a storage capacitor Cst.

The driving circuit DC and the light-emitting device 300 of each sub-pixel SP can be supported by a device substrate 100. The device substrate 100 can include various materials. For example, the device substrate 100 can be a wafer made of a semiconductor material, such as silicon. At least one of the driving circuit DC in each sub-pixel SP can be formed within the device substrate 100. Thus, in the display apparatus according to the embodiment of the present disclosure, the density of the pixel circuit DC formed in each sub-pixel SP can be improved. Therefore, in the display apparatus according to the embodiment of the present disclosure, the resolution of the image can be improved.

The first thin film transistor TR1 of each sub-pixel SP can transmit the data signal to the second thin film transistor TR2 of the corresponding sub-pixel SP according to the gate signal. For example, the first thin film transistor TR1 of each sub-pixel SP can be a switching thin film transistor. The first thin film transistor TR1 of each sub-pixel SP can include a first well region, a first drain region, a first source region, a first gate electrode, a first drain electrode and a first source electrode. For example, the first gate electrode of the first thin film transistor TR1 of each sub-pixel SP can be electrically connected to the corresponding gate line GL, and the first drain electrode of the first thin film transistor TR1 of each sub-pixel SP can be electrically connected to the corresponding date line DL.

The first well region, the first drain region and the first source region can be formed within the device substrate 100. For example, the first well region, the first drain region and the first source region can be formed by a process of doping the device substrate 100 with conductive impurities. The first drain region and the first source region can include different conductive impurities from the first well region. For example, the first well region can include P-type impurities, and the first drain region and the first source region can include N-type impurities. The first drain region and the first source region can be formed in the first well region. For example, a portion of the first well region disposed between the first drain region and the first source region in each sub-pixel SP can function as a first channel region of the first thin film transistor TR1 in the corresponding sub-pixel SP.

The first gate electrode can be disposed on the device substrate 100. The first gate electrode can be disposed between the first drain region and the first source region. For example, the first gate electrode of each sub-pixel SP can overlap the portion of the first well region, which functions as the first channel region in the corresponding sub-pixel SP. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the device substrate 100. The first gate electrode can be insulated from the device substrate 100. For example, the first drain region can be electrically connected to the first source region according to a voltage applied to the first gate electrode.

The first drain electrode can be disposed on the device substrate 100. The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region. The first drain electrode can be insulated from the first gate electrode.

The first source electrode can be disposed on the device substrate 100. The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region. The first source electrode can be insulated from the first gate electrode. The first source electrode can be spaced apart from the first drain electrode.

The second thin film transistor TR2 of each sub-pixel SP can generate the driving current corresponding to the data signal. For example, the second thin film transistor TR2 of each sub-pixel SP can be a driving thin film transistor. The second thin film transistor TR2 of each sub-pixel SP can include a second well region 102w, a second drain region 102d, a second source region 102s, a second gate electrode 223, a second drain electrode 225 and a second source electrode 227. For example, the second gate electrode 223 of the second thin film transistor TR2 of each sub-pixel SP can be electrically connected to the first source electrode of the corresponding sub-pixel SP, and the second drain electrode 225 of the second thin film transistor TR2 of each sub-pixel SP can be electrically connected to the corresponding power voltage supply line PL. The light-emitting device 300 of each sub-pixel SP can be electrically connected to the second source electrode 227 of the second thin film transistor TR2 of the corresponding sub-pixel SP.

The second well region 102w, the second drain region 102d and the second source region 102s can be formed within the device substrate 100. For example, the second well region 102w, the second drain region 102d and the second source region 102s can be formed by a process of doping the device substrate 100 with conductive impurities. The second drain region 102d and the second source region 102s can include different conductive impurities from the second well region 102w. The second thin film transistor TR2 of each sub-pixel SP can have different electrical characteristics from the first thin film transistor TR1 of the corresponding sub-pixel SP. For example, the second well region 102w can include N-type impurities, and the second drain region 102d and the second source region 102s can include P-type impurities.

The second well region 102w can include conductive impurities same as the first drain region and the first source region. The second well region 102w can be formed a same process as the first drain region and the first source region. For example, the second well region 102w can be formed simultaneously with the first drain region and the first source region. The second drain region 102d and the second source region 102s can include conductive impurities same as the first well region. The second drain region 102d and the second source region 102s can be formed by a same process as the first well region. For example, the second drain region 102d and the second source region 102s can be formed simultaneously with the first well region. Thus, in the display apparatus according to the embodiment of the present disclosure, process efficiency can be improved.

The second drain region 102d and the second source region 102s can be formed within the second well region 102w. For example, a portion of the second well region 102w disposed between the second drain region 102d and the second source region 102s in each sub-pixel SP can function as a second channel region of the second thin film transistor TR2 in the corresponding sub-pixel SP.

The second gate electrode 223 can be disposed on the device substrate 100. The second gate electrode 223 can be disposed between the second drain region 102d and the second source region 102s. For example, the second gate electrode 223 of each sub-pixel SP can overlap the portion of the second well region 102w which functions as the second channel region in the corresponding sub-pixel SP. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the device substrate 100. The second gate electrode 223 can be insulated from the device substrate 100. For example, the portion of the second well region 102w functioning as the second channel region can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be disposed on the device substrate 100. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. The second drain electrode 225 can be disposed on a different layer from the second gate electrode 223. The second drain electrode 225 can be spaced apart from the device substrate 100. The second drain electrode 225 can be electrically connected to the second drain region 102d. The second drain electrode 225 can be insulated from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be disposed on the device substrate 100. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. The second source electrode 227 can be spaced apart from the device substrate 100. The second source electrode 227 can be electrically connected to the second source region 102s. The second source electrode 227 can be insulated from the second gate electrode 223.

The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225.

The storage capacitor Cst of each sub-pixel SP can maintain a signal applied to the second gate electrode 223 of the corresponding sub-pixel SP for one frame. For example, the storage capacitor Cst of each sub-pixel SP can be electrically connected between the second gate electrode 223 and the second source electrode 227 of the corresponding sub-pixel SP. The storage capacitor Cst of each sub-pixel SP can have a stacked structure of capacitor electrodes. For example, the storage capacitor Cst of each sub-pixel SP can include a first capacitor electrode electrically connected to the second gate electrode 223 of the corresponding sub-pixel SP and a second capacitor electrode electrically connected to the second source electrode 227 of the corresponding sub-pixel SP. The storage capacitor Cst of each sub-pixel SP can be formed by using a process of forming the first thin film transistor TR1 and the second thin film transistor TR2 in the corresponding sub-pixel SP. For example, the first capacitor electrode of each sub-pixel SP can be formed on a same layer as the second gate electrode 223 of the corresponding sub-pixel SP, and the second capacitor electrode of each sub-pixel SP can be formed on a same layer as the second source electrode 227 of the corresponding sub-pixel SP. The first capacitor electrode of each sub-pixel SP can include a same material as the second gate electrode 223 of the corresponding sub-pixel SP, and the second capacitor electrode of each sub-pixel SP can include a same material as the second source electrode 227 of the corresponding sub-pixel SP. The first capacitor electrode of each sub-pixel SP can be formed by a same process as the second gate electrode 223 of the corresponding sub-pixel SP, and the second capacitor electrode of each sub-pixel SP can be formed by a same process as the second source electrode 227 of the corresponding sub-pixel SP. For example, the first capacitor electrode of each sub-pixel SP can be formed simultaneously with the second gate electrode 223 of the corresponding sub-pixel SP, and the second capacitor electrode of each sub-pixel SP can be formed simultaneously with the second source electrode 227 of the corresponding sub-pixel SP.

Thus, in the display apparatus according to the embodiment of the present disclosure, process efficiency can be improved.

A plurality of insulating layers 110, 120, 130 and 140 for preventing unnecessary electrical connection can be disposed on the device substrate 100. For example, a gate insulating layer 110, an interlayer insulating layer 120, a planarization layer 130 and fences 140 can be disposed on the device substrate 100.

The gate insulating layer 110 can be disposed on the device substrate 100. The first gate electrode and the second gate electrode 223 of the each sub-pixel SP can be insulated from the device substrate 100 by the gate insulating layer 110. For example, an upper surface of the device substrate 100 toward the first gate electrode and the second gate electrode 223 of each sub-pixel SP can be covered by the gate insulating layer 110. The gate insulating layer 110 can be in direct contact with the upper surface of the device substrate 100. For example, the first well region, the first drain region, the first source region, the second well region 102w, the second drain region 102d and the second source region 102s of each sub-pixel SP can be covered by the gate insulating layer 110. The first gate electrode and the second gate electrode 223 of each sub-pixel SP can be disposed on the gate insulating layer 110. The gate insulating layer 110 can include an insulating material. For example, the gate insulating layer 110 can include an inorganic insulating material, such as silicon oxide (SiOx) and silicon nitride (SiNx).

The interlayer insulating layer 120 can be disposed on the gate insulating layer 110. The first gate electrode of each sub-pixel SP can be insulated from the first drain electrode and the first source electrode of the corresponding sub-pixel SP, and the second gate electrode 223 of each sub-pixel SP can be insulated from the second drain electrode 225 and the second source region 227 of the corresponding sub-pixel SP. For example, the interlayer insulating layer 120 can cover the first gate electrode and the second gate electrode 223 of each sub-pixel SP. The first drain electrode, the first source electrode, the second drain electrode 225 and the second source electrode 227 of each sub-pixel SP can be disposed on the interlayer insulating layer 120. The interlayer insulating layer 120 can include an insulating material. For example, the interlayer insulating layer 120 can include an inorganic insulating material, such as silicon oxide (SiOx) and silicon nitride (SiNx).

The planarization layer 130 can be disposed on the interlayer insulating layer 120. The planarization layer 130 can be configure to protect the pixel driving circuit DC of each sub-pixel SP. The planarization layer 130 can remove a thickness difference due to the pixel driving circuit DC of each sub-pixel SP. For example, the first drain electrode, the first source electrode, the second drain electrode 225 and the second source electrode 227 of each sub-pixel SP can be covered by the planarization layer 130. An upper surface of the planarization layer 130 opposite to the device substrate 100 can be a flat surface. For example, the upper surface of the planarization layer 130 can be parallel to the upper surface of the device substrate 100. The planarization layer 130 can include an insulating material. The planarization layer 130 can include a different material from the interlayer insulating layer 120. The planarization layer 130 can include a material having a high fluidity. For example, the planarization layer 130 can include an organic insulating material.

The light-emitting device 300 of each sub-pixel SP can be disposed on the planarization layer 130. For example, the first electrode 310, the light-emitting unit 320 and the second electrode 330 of each sub-pixel SP can be sequentially stacked on the planarization layer 130 of the corresponding sub-pixel SP. The first electrode 310 of each sub-pixel SP can be electrically connected to the driving circuit DC of the corresponding sub-pixel SP. For example, the first electrode 310 of each sub-pixel SP can be in direct contact with the second source electrode 227 of the corresponding sub-pixel SP by penetrating the planarization layer 130. The first electrode 310 of each sub-pixel SP can include a portion directly contacting the upper surface of the planarization layer 130. The light-emitting unit 320 and the second electrode 330 of each sub-pixel SP can be stacked on the portion of the corresponding first electrode 310 directly contacting the upper surface of the planarization layer 130. Thus, in the display apparatus according to the embodiment of the present disclosure, the luminance deviation due to the generating location of the light emitted from the light-emitting device 300 of each sub-pixel SP can be prevented.

The fences 140 can be disposed on the planarization layer 130. The fences 140 can define an emission area R-EA, G-EA and B-EA in each sub-pixel SP. An edge of the first electrode 310 in each sub-pixel SP can be covered by the fences 140. For example, a portion of the first electrode 310 exposed by the fences 140 in each sub-pixel SP can be the emission area R-EA, G-EA and B-EA in the corresponding sub-pixel SP. The light-emitting unit 320 and the second electrode 330 of each sub-pixel SP can be stacked on the portion of the corresponding first electrode 310 exposed by the fences 140. The portion of the first electrode 310 disposed in the emission area R-EA, G-EA and B-EA in each sub-pixel SP can be in direct contact with the upper surface of the planarization layer 130. The fences 140 can include an insulating material. For example, the fences 140 can include an inorganic insulating material, such as silicon oxide (SiOx) and silicon nitride (SiNx). Each of the fences 140 can be a linear insulating layer with a constant thickness. The first electrode 310 of each sub-pixel SP can be insulated from the first electrode 310 of adjacent sub-pixel SP by the fences 140.

Light emitted from the light-emitting device 300 of each sub-pixel SP can display a same color as light emitted from the light-emitting device 300 of adjacent sub-pixel SP. For example, the light emitted from the light-emitting device 300 of each sub-pixel SP can be white light. The light-emitting unit 320 of each sub-pixel SP can have a stacked structure same as the light-emitting unit 320 of adjacent sub-pixel SP. The first emission stack 321, the charge generation layer 322 and the second emission stack 323 of each sub-pixel SP can be formed by a same process as the first emission stack 321, the charge generation layer 322 and the second emission stack 323 of adjacent sub-pixel SP. For example, the first emission stack 321, the charge generation layer 322 and the second emission stack 323 of each sub-pixel SP can be formed simultaneously with the first emission stack 321, the charge generation layer 322 and the second emission stack 323 of adjacent sub-pixel SP, respectively.

A region disposed between the emission areas R-EA, G-EA and B-EA can be defined as a non-emission area NEA. For example, the fences 140 of each pixel area PA can be disposed on the non-emission area NEA of the corresponding pixel area PA. A separation trench ST can be disposed within the non-emission area NEA. The separation trench ST can extend along between adjacent emission areas R-EA, G-EA and B-EA. For example, each of the emission areas R-EA, G-EA and B-EA can be surrounded by the separation trench ST. The separation trench ST can be spaced apart from the fences 140. Each of the fences 140 can be disposed outside the separation trench ST. For example, the separation trench ST can be disposed between adjacent fences 140. A horizontal width of the separation trench ST can be smaller than a horizontal width of the non-emission area NEA.

The separation trench ST can extend in a direction of the device substrate 100. For example, a portion of the separation trench ST can be surrounded by the planarization layer 130. The separation trench ST can have a groove shape in which a portion of the planarization layer 130 is removed. The charge generation layer 322 of each sub-pixel SP can be separated from the charge generation layer 322 of adjacent sub-pixel SP. The first emission stack 321 of each sub-pixel SP can be separated from the first emission stack 321 of adjacent sub-pixel SP. For example, an air-gap AR can be formed within the separation trench ST. Thus, in the display apparatus according to the embodiment of the present disclosure, malfunction of the light-emitting device 300 disposed in each sub-pixel SP due to leakage current can be prevented. And, in the display apparatus according to the embodiment of the present disclosure, the density of the light-emitting devices 300 can be improved. Therefore, in the display apparatus according to the embodiment of the present disclosure, the resolution of the image can be improved.

A voltage applied to the second electrode 330 of each sub-pixel SP can be a same as a voltage applied to the second electrode 330 of adjacent sub-pixel SP. For example, the second electrode 330 of each sub-pixel SP can be electrically connected to the second electrode 330 of adjacent sub-pixel SP. The second electrode 330 of each sub-pixel SP can include a same material as the second electrode 330 of adjacent sub-pixel SP. The second electrode 330 of each sub-pixel SP can be formed by a same process as the second electrode 330 of adjacent sub-pixel SP. For example, the second electrode 330 of each sub-pixel SP can be formed simultaneously with the second electrode 330 of adjacent sub-pixel SP. The second electrode 330 of each sub-pixel SP can be in direct contact with the second electrode 330 of adjacent sub-pixel SP. For example, the second electrode 330 can include a region overlapping with the separation trench ST. Thus, in the display apparatus according to the embodiment of the present disclosure, a process of forming the second electrode 330 in each sub-pixel SP can be simplified. Luminance of the light emitted from the light-emitting device 300 of each sub-pixel SP can be adjusted by the data signal applied to the driving circuit DC of the corresponding sub-pixel SP.

An encapsulation structure 400 can be disposed on the light-emitting device 300 of each sub-pixel SP. The encapsulation structure 400 can prevent damage of the light-emitting devices 300 due to external moisture and impact. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can be an inorganic encapsulating layer including an inorganic insulating material, such as silicon oxide (SiOx) and silicon nitride (SiNx), and the second encapsulating layer 420 can be an organic encapsulating layer including an organic insulating material. A thickness difference due to the light- emitting device 300 of each sub-pixel SP can be removed by the second encapsulating layer 420. For example, an upper surface of the encapsulation structure 400 opposite to the device substrate 100 can be a flat surface. The upper surface of the encapsulation structure 400 can be parallel to the upper surface of the device substrate 100. Thus, in the display apparatus according to the embodiment of the present disclosure, the damage of the light-emitting device 300 in each sub-pixel SP due to the external moisture and impact can be effectively prevented. For example, in the display apparatus according to the exemplary embodiment of the present disclosure, the penetration of the external moisture and oxygen may be effectively blocked or at least reduced.

The sub-pixels SP in each pixel area PA can realize different colors. Each of the pixel areas PA can include a first sub-pixel realizing a first color, a second sub-pixel realizing a second color and a third sub-pixel realizing a third color. For example, each of the pixel areas PA can include a red sub-pixel realizing a red color, a green sub-pixel realizing a green color and a blue sub-pixel realizing a blue color. The fences 140 of each pixel area PA can define a red emission area R-EA in the red sub-pixel, a green emission area G-EA in the green sub-pixel, and a blue emission area B-EA in the blue sub-pixel. Color filters 500R, 500G and 500B to realize colors of the emission areas R-EA, G-EA and B-EA in each pixel area PA can be disposed on the emission areas R-EA, G-EA and B-EA of the sub-pixels SP in the corresponding pixel area PA. The color filter 500R, 500G and 500B of each sub-pixel SP can overlap the emission area R-EA, G-EA and B-EA of the corresponding sub-pixel SP. For example, a red color filter 500R overlapping with the red emission area R-EA, a green color filter 500G overlapping with the green emission area G-EA and a blue color filter 500B overlapping with the blue emission area B-EA can be disposed on each pixel area PA. The color filter 500R, 500G and 500B of each emission area R-EA, G-EA and B-EA can have a greater size than the corresponding emission area R-EA, G-EA and B-EA. For example, a boundary between adjacent color filters 500R, 500G and 500B can overlap the separation trench ST. Thus, in the display apparatus according to the embodiment of the present disclosure, the light emitted from the light-emitting device 300 of each sub-pixel PA must pass through one of the color filters 500R, 500G and 500B in the corresponding pixel area PA. Therefore, in the display apparatus according to the embodiment of the present disclosure, light leakage can be prevented.

A barrier 610 and lens structures 620 can be disposed between the encapsulation structure 400 and the color filters 500R, 500G and 500B. The barrier 610 can be disposed on the non-emission area NEA. The barrier 610 can be disposed outside the emission areas R-EA, G-EA and B-EA. For example, the barrier 610 can overlap the separation trench ST. The barrier 610 can extend along between the emission areas R-EA, G-EA and B-EA. For example, the pixel areas PA can be disposed side by side in a first direction and a second direction perpendicular to the first direction, the emission areas R-EA, G-EA and B-EA of each pixel area PA can be disposed side by side in the second direction, and the barrier 610 can include a first barrier region 611 extending in the first direction and a second barrier region 612 extending in the second direction. The second barrier region 612 can be in direct contact with the first barrier region 611. For example, a plane of the barrier 610 can have a mesh shape, and the emission areas R-EA, G-EA and B-EA can be disposed in a matrix form within regions defined by the barrier 610. Each of the emission areas R-EA, G-EA and B-EA in each sub-pixel SP can be surrounded by the barrier 610.

Each of the emission areas R-EA, G-EA and B-EA in each pixel area PA can display a same color as the emission area R-EA, G-EA and B-EA of adjacent pixel area PA in the first direction. For example, the color filters 500R, 500G and 500B of each pixel area PA can be arranged in a same order as the color filters 500R, 500G and 500B of adjacent pixel area PA in the second direction. Each of the emission areas R-EA, G-EA and B-EA in each pixel area PA can include a same material as the emission area R-EA, G-EA and B-EA of adjacent pixel area PA in the first direction.

The barrier 610 can include a material having a high reflectance. For example, the barrier 610 can include a metal. The barrier 610 can be in direct contact with the encapsulation structure 400 and the color filters 500R, 500G and 500B. For example, a thickness of the barrier 610 can be a same as a vertical distance between the third encapsulating layer 430 and the color filters 500R, 500G and 500B. The boundaries between the color filters 500R, 500G and 500B can overlap the barrier 610. That is, the barrier 610 can be disposed on the non-emission area NEA. Thus, in the display apparatus according to the embodiment of the present disclosure, the light emitted from the light-emitting device 300 of each emission area R-EA, G-EA and B-EA to the color filer 500R, 500G and 500B of adjacent emission area R-EA, G-EA and B-EA can be reflected by the barrier 610 in toward the inside of the corresponding emission area R-EA, G-EA and B-EA. Therefore, in the display apparatus according to the embodiment of the present disclosure, color mixing can be prevented. And, in the display apparatus according to the embodiment of the present disclosure, light extraction efficiency of each emission area R-EA, G-EA and B-EA can be improved. That is, in the display apparatus according to the embodiment of the present disclosure, the luminance of each emission area R-EA, G-EA and B-EA can be improved.

The lens structures 620 can be disposed on the emission areas R-EA, G-EA and B-EA. For example, each of the lens structures 620 can overlap one of the emission areas R-EA, G-EA and B-EA. A space between the encapsulation structure 400 and the color filters 500R, 500G and 500B can be completely filled by the barrier 610 and the lens structures 620. For example, a side of each lens structure 620 can be in direct contact with the barrier 610. Each of the lens structures 620 can have a structure in which at least three layers are stacked. For example, each of the lens structures 620 can have a stacked structure of a first lens insulating layer 621, a second lens insulating layer 622 and a lens passivation layer 623. The first lens insulating layer 621, the second lens insulating layer 622 and the lens passivation layer 623 can be are sequentially stacked on the encapsulation structure 400.

The first lens insulating layer 621 can be disposed close to the encapsulation structure 400. The first lens insulating layer 621 can be in direct contact with the upper surface of the encapsulation structure 400. For example, a lower surface of the first lens insulating layer 621 toward the device substrate 100 can be in direct contact with the upper surface of the third encapsulating layer 430 of the encapsulation structure 400. The first lens insulating layer 621 can include an insulating material. The first lens insulating layer 621 can include a transparent material. The first lens insulating layer 621 can be formed by a coating process. For example, the first lens insulating layer 621 can include an organic insulating material.

An upper surface USI of the first lens insulating layer 621 toward the color filters 500R, 500G and 500B can have a concave shape toward the device substrate 100. A thickness of the first lens insulating layer 621 disposed in each emission area R-EA, G-EA and B-EA can gradually increase from the central area CTA of the corresponding emission area R-EA, G-EA and B-EA toward the barrier 610. As shown, a second thickness TH2 of the first lens insulating layer 621 at the barrier 610 is greater than a first thickness TH1 of the first lens insulating layer 621 at a center of each emission area R-EA, G-EA and B-EA. Here, a vertical distance between the device substrate 100 and the upper surface USI of the first lens insulating layer 621 disposed in each emission area R-EA, G-EA and B-EA can gradually increase from the central area of the corresponding emission area R-EA, G-EA and B-EA toward the barrier 610. For instance, a second vertical distance VD2 at the barrier 610 is greater than a first vertical distance VD1 at a center of each emission area R-EA, G-EA and B-EA. The upper surface of the first lens insulating layer 621 formed on each emission area R-EA, G-EA and B-EA can have a concave shape toward the device substrate 100.

The second lens insulating layer 622 can be disposed on the upper surface of the first lens insulating layer 621. The second lens insulating layer 622 can be in direct contact with the first lens insulating layer 621. For example, a lower surface LS2 of the second lens insulating layer 622 toward the device substrate 100 can be in direct contact with the upper surface USI of the first lens insulating layer 621. The lower surface LS2 of the second lens insulating layer 622 can have a same shape as the upper surface USI of the first lens insulating layer 621. For example, a boundary between the first lens insulating layer 621 and the second lens insulating layer 622 can have a convex shape toward the device substrate 100. The upper surface USI of the first lens insulating layer 621 can be completely covered by the lower surface LS2 of the second lens insulating layer 622. For example, a side of the first lens insulating layer 621 and a side of the second lens insulating layer 622 within each emission area R-EA, G-EA and B-EA can be in direct contact with the barrier 610.

The second lens insulating layer 622 can include an insulating material. The second lens insulating layer 622 can include a transparent material. The second lens insulating layer 622 can be formed by a coating process. For example, the second lens insulating layer 622 can include an organic insulating material. A refractive index of the second lens insulating layer 622 can be larger than a refractive index of the first lens insulating layer 621. For example, the second lens insulating layer 622 can include a different material from the first lens insulating layer 621. Thus, in the display apparatus according to the embodiment of the present disclosure, the light passing through the first lens insulating layer 621 of each emission area R-EA, G-EA and B-EA can be refracted at the boundary between the first lens insulating layer 621 and the second lens insulating layer 622 of the corresponding emission area R-EA, G-EA and B-EA. For example, the light passing through the first lens insulating layer 621 of each emission area R-EA, G-EA and B-EA can be refracted toward the central area of the corresponding emission area R-EA, G-EA and B-EA at the boundary between the first lens insulating layer 621 and the second lens insulating layer 622 on the corresponding emission area R-EA, G-EA and B-EA. That is, in the display apparatus according to the embodiment of the present disclosure, the boundary between the first lens insulating layer 621 and the second lens insulating layer 622 in each emission area R-EA, G-EA and B-EA can function as a lens concentrating light. Therefore, in the display apparatus according to the embodiment of the present disclosure, the light emitted from the light-emitting device 300 of each emission area R-EA, G-EA and B-EA can be primarily concentrated at the boundary between the first lens insulating layer 621 and the second lens insulating layer 622 in the corresponding emission area R-EA, G-EA and B-EA.

An upper surface US2 of the second lens insulating layer 622 toward the color filters 500R, 500G and 500B can have a concave shape toward the device substrate 100. For example, a vertical distance between the device substrate 100 and the upper surface US2 of the second lens insulating layer 622 in each emission area R-EA, G-EA and B-EA can be gradually increase from the central area of the corresponding emission area R-EA, G-EA and B-EA toward the barrier 610. The upper surface US2 of the second lens insulating layer 622 can have a same shape as the upper surface USI of the first lens insulating layer 621. For example, the upper surface US2 of the second lens insulating layer 622 can have a same curvature as the upper surface USI of the first lens insulating layer 621.

The lens passivation layer 623 can be disposed on the upper surface US2 of the second lens insulating layer 622. The lens passivation layer 623 can be in direct contact with the second lens insulating layer 622. For example, a lower surface LS3 of the lens passivation layer 623 toward the device substrate 100 can be in direct contact with the upper surface US2 of the second lens insulating layer 622. The lower surface LS3 of the lens passivation layer 623 can have a same shape as the upper surface US2 of the second lens insulating layer 622. For example, a boundary between the second lens insulating layer 622 and the lens passivation layer 623 can have a convex shape toward the device substrate 100. The upper surface US2 of the second lens insulating layer 622 can be completely covered by the lower surface of the lens passivation layer 623. For example, a side of the lens passivation layer 623 in each emission area R-EA, G-EA and B-EA can be in direct contact with the barrier 610.

A refractive index of the lens passivation layer 623 can be larger than the refractive index of the second lens insulating layer 622. Thus, in the display apparatus according to the embodiment of the present disclosure, the light passing through the second lens insulating layer 622 of each emission area R-EA, G-EA and B-EA can be refracted at the boundary between the second lens insulating layer 622 and the lens passivation layer 623 of the corresponding emission area R-EA, G-EA and B-EA. For example, the light passing through the second lens insulating layer 622 of each emission area R-EA, G-EA and B-EA can be refracted toward the central area CTA of the corresponding emission area R-EA, G-EA and B-EA at the boundary between the second lens insulating layer 622 and the lens passivation layer 623 of the corresponding emission area R-EA, G-EA and B-EA. That is, in the display apparatus according to the embodiment of the present disclosure, the boundary between the second lens insulating layer 622 and the lens passivation layer 623 in each emission area R-EA, G-EA and B-EA can function as a lens. In the display apparatus according to the embodiment of the present disclosure, the light primary concentrated at the boundary between the first lens insulating layer 621 and the second lens insulating layer 622 of each emission area R-EA, G-EA and B-EA can be secondarily concentrated at the boundary between the second lens insulating layer 622 and the lens passivation layer 623 of the corresponding emission area R-EA, G-EA and B-EA. Therefore, in the display apparatus according to the embodiment of the present disclosure, the concentration efficiency of each emission area R-EA, G-EA and B-EA can be greatly improved by the lens structure 620 of the corresponding emission area R-EA, G-EA and B-EA.

The lens passivation layer 623 can include an insulating material. The lens passivation layer 623 can include a transparent material. The lens passivation layer 623 can include a different material from the second lens insulating layer 622. The lens passivation layer 623 can include a material harder than the second lens insulating layer 622. For example, the lens passivation layer 623 can include an inorganic insulating material, such as silicon oxide (SiOx) and silicon nitride (SiNx). Thus, in the display apparatus according to the embodiment of the present disclosure, damage of the first lens insulating layer 621 and damage of the second lens insulating layer 622 due to the external impact can be prevented by the lens passivation layer 623. For example, in the display apparatus according to the embodiment of the present disclosure, the boundary between the first lens insulating layer 621 and the second lens insulating layer 622 and the boundary between the second lens insulating layer 622 and the lens passivation layer 623 can not be deformed by the external impact. That is, in the display apparatus according to the embodiment of the present disclosure, the concentration efficiency by the lens structure 620 of each emission area R-EA, G-EA and B-EA can not be changed by the external impact. Therefore, in the display apparatus according to the embodiment of the present disclosure, the differences in the concentration efficiency of the emission areas R-EA, G-EA and B-EA due to the differences in shapes of the lens structures 620 can be prevented. And, in the display apparatus according to the embodiment of the present disclosure, the luminance deviation due to the differences in the concentration efficiency of the emission areas R-EA, G-EA and B-EA can be prevented.

The lens passivation layer 623 of each emission area R-EA, G-EA and B-EA can be in direct contact with the color filter 500R, 500G and 500B of the corresponding emission area R-EA, G-EA and B-EA. For example, an upper surface US3 of the lens passivation layer 623 toward the color filters 500R, 500G and 500B in each emission area R-EA, G-EA and B-EA can be a flat surface. The upper surface US3 of the lens passivation layer 623 of each emission area R-EA, G-EA and B-EA can be in direct contact with a lower surface of the color filter 500R, 500G and 500B of the corresponding emission area R-EA, G-EA and B-EA. The upper surface US3 of the lens passivation layer 623 in each emission area R-EA, G-EA and B-EA can be parallel to the upper surface USO of the encapsulation structure 400.

The color filter 500R, 500G and 500B of each emission area R-EA, G-EA and B-EA can have a refractive index smaller than the lens passivation layer 623 of the corresponding emission area R-EA, G-EA and B-EA. Thus, in the display apparatus according to the embodiment of the present disclosure, the light passing through the lens structure 620 of each emission area R-EA, G-EA and B-EA can be diffused at a boundary between the lens passivation layer 623 and the color filter 500R, 500G and 500B in the corresponding emission area R-EA, G-EA and B-EA. That is, in the display apparatus according to the embodiment of the present disclosure, the viewing angle characteristics of each emission area R-EA, G-EA and B-EA can be adjusted by the difference in the refractive index between the lens passivation layer 623 and the color filter 500R, 500G and 500B of the corresponding emission area R-EA, G-EA and B-EA. Therefore, in the display apparatus according to the embodiment of the present disclosure, the light extraction efficiency and the viewing angle characteristics of each emission area R-EA, G-EA and B-EA can be improved.

A filter passivation layer 700 can be disposed on the color filters 500R, 500G and 500B of each pixel area PA. The filter passivation layer 700 can prevent the damage of the color filters 500R, 500G and 500B due to the external impact and moisture. The filter passivation layer 700 can include an insulating material. For example, the filter passivation layer 700 can include at least one of inorganic insulating material and organic insulating material. The filter passivation layer 700 can have a multi-layer structure. For example, the filter passivation layer 700 can have a structure in which an inorganic passivation layer made of an inorganic insulating material is formed on an organic passivation layer made of an organic insulating material. Thus, in the display apparatus according to the embodiment of the present disclosure, the damage of the color filters 500R, 500G and 500B in each pixel area PA due to the external impact and moisture can be effective prevented.

Accordingly, the display apparatus according to the embodiment of the present disclosure can include the lens structure 620 disposed between the encapsulation structure 400 and the color filter 500R, 500G and 500B of each emission area R-EA, G-EA and B-EA, and the barrier 610 surrounding the lens structure 620, wherein the side of the lens structure 620 on each emission area R-EA, G-EA and B-EA can be in direct contact with the barrier 610, wherein the lens structure 620 of each emission area R-EA, G-EA and B-EA can include the first lens insulating layer 621, the second lens insulating layer 622 and the lens passivation layer 623, which are sequentially stacked on the encapsulation structure 400, wherein the second lens insulating layer 622 can have a refractive index larger than the first lens insulating layer 621, wherein the lens passivation layer 623 can have a refractive index larger than the second lens insulating layer 622, and wherein the boundary between the first lens insulating layer 621 and the second lens insulating layer 622 and the boundary between the second lens insulating layer 622 and the lens passivation layer 623 in each emission area R-EA, G-EA and B-EA can have a convex shape toward the device substrate 100. Thus, in the display apparatus according to the embodiment of the present disclosure, the light emitted from the light-emitting device 300 of each emission area R-EA, G-EA and B-EA can be primarily concentrated at the boundary between the first lens insulating layer 621 and the second lens insulating layer 622 in in the corresponding emission area R-EA, G-EA and B-EA, and can be secondarily concentrated at the boundary between the second lens insulating layer 622 and the lens passivation layer 623 in the corresponding emission area R-EA, G-EA and B-EA. And, in the display apparatus according to the embodiment of the present disclosure, the light emitted from the light-emitting device 300 of each emission area R-EA, G-EA and B-EA toward the color filter 500R, 500G and 500B of adjacent emission area R-EA, G-EA and B-EA can be reflected toward the central area CTA of the corresponding emission area R-EA, G-EA and B-EA by the barrier 610. Therefore, in the display apparatus according to the embodiment of the present disclosure, the concentration efficiency and light extraction efficiency of each emission area R-EA, G-EA and B-EA can be improved. And, in the display apparatus according to the embodiment of the present disclosure, the luminance deviation due to the differences in the concentration efficiency of the emission areas R-EA, G-EA and B-EA can be prevented. Thereby, in the display apparatus according to the embodiment of the present disclosure, the quality of the image can be improved.

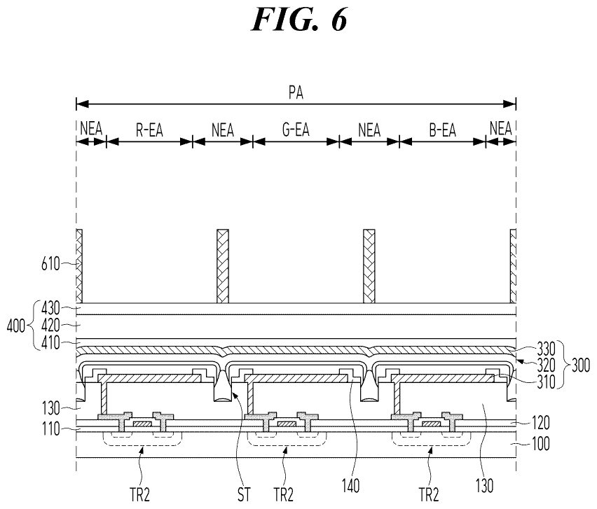

FIGS. 6 to 8 are views sequentially showing a method of forming the display apparatus according to the embodiment of the present disclosure.

The method of forming the display apparatus according to the embodiment of the present disclosure will be described with reference to FIGS. 4 to 8. First, as shown in FIG. 6, the method of forming the display apparatus according to the embodiment of the present disclosure can include a step of forming the gate insulating layer 110, the interlayer insulating layer 120, the planarization layer 130, the fences 140, the separation trench ST, the driving circuits including the second thin film transistor TR2, the light-emitting devices 300 and the encapsulation structure 400 on the device substrate 100, and a step of forming the barrier 610 on the encapsulation structure 400 in the non-emission area NEA.

Each of the light-emitting devices 300 can be formed to overlap one of the emission areas R-EA, G-EA and B-EA defined by the non-emission area NEA. The fences 140 and the separation trench ST can be formed to overlap the non-emission area NEA. For example, the barrier 610 can be formed to overlap the separation trench ST. The fences 140 can be formed outside the separation trench ST.

The barrier 610 can be formed outside the emission areas R-EA, G-EA and B-EA. For example, the upper surface USO of the encapsulation structure 400 on each emission area R-EA, G-EA and B-EA can be exposed by the barrier 610. The barrier 610 can be formed of a material having relative high reflectance. For example, the barrier 610 can be formed of a metal.

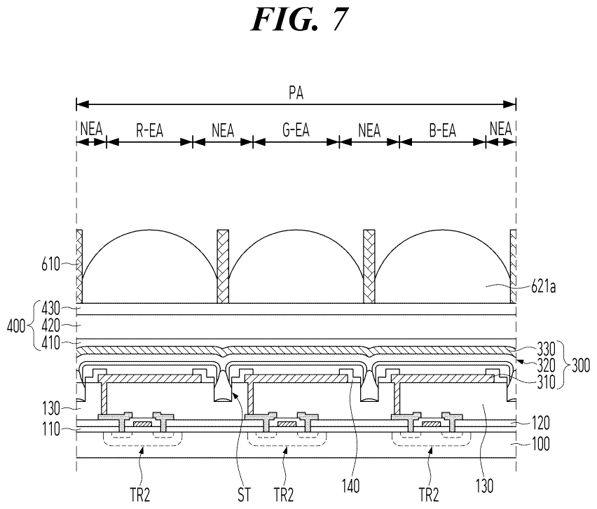

As shown in FIG. 7, the method of forming the display apparatus according to the embodiment of the present disclosure can include a step of forming a first preliminary insulating layer 621a on the encapsulation structure 400 of each emission area R-EA, G-EA and B-EA.

The first preliminary insulating layer 621a can be formed of an insulating material. The first preliminary insulating layer 621a can be formed of a transparent material. For example, the first preliminary insulating layer 621a can be formed of an organic insulating material. The step of forming the first preliminary insulating layer 621a on each emission area R-EA, G-EA and B-EA can include a coating process. For example, the step of forming the first preliminary insulating layer 621a on each emission area R-EA, G-EA and B-EA can include a step of spraying an organic insulating material on the encapsulation structure 400 exposed by the barrier 610 using a nozzle of ink-jet equipment. An upper surface of the first preliminary insulating layer 621a formed on each emission area R-EA, G-EA and B-EA, which is opposite to the encapsulation structure 400, can have a convex curved shape in a direction opposite to the device substrate 100.

The encapsulation structure 400 of each emission area R-EA, G-EA and B-EA exposed by the barrier 610 can be completely covered by the first preliminary insulating layer 621a formed on the corresponding emission area R-EA, G-EA and B-EA. For example, a side of the preliminary insulating layer 621a formed on each emission area R-EA, G-EA and B-EA can be in direct contact with the barrier 610.

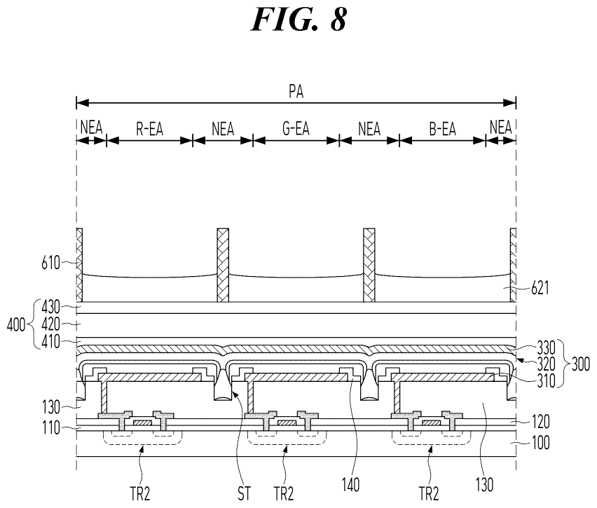

As shown in FIG. 8, the method of forming the display apparatus according to the embodiment of the present disclosure can include a step of forming the first lens insulating layer 621 of each emission area R-EA, G-EA and B-EA.

The step of forming the first lens insulating layer 621 of each emission area R-EA, G-EA and B-EA can include a step of curing the first preliminary insulating layer 621a of each emission area R-EA, G-EA and B-EA. The step of curing the first preliminary insulating layer 621a of each emission area R-EA, G-EA and B-EA can include a drying process. Thus, in the display apparatus according to the embodiment of the present disclosure, a volume of the first preliminary insulating layer 621a on each emission area R-EA, G-EA and B-EA can be reduced by evaporation of the solvent. A volume reduced at an edge of the first preliminary insulating layer 621a directly contacting the barrier 610 can be smaller than a volume reduced at the central area of the first preliminary insulating layer 621a spaced apart from the barrier 610 in the drying process. Therefore, in the method of forming the display apparatus according to the embodiment of the present disclosure, the thickness of the first lens insulating layer 621 formed on each emission area R-EA, G-EA and B-EA can increase from the central area of the corresponding emission area R-EA, G-EA and B-EA toward the barrier 610. For example, a vertical distance between the device substrate 100 and the upper surface USI of the first lens insulating layer 621 disposed in each emission area R-EA, G-EA and B-EA can gradually increase from the central area CTA of the corresponding emission area R-EA, G-EA and B-EA toward the barrier 610. That is, in the method of forming the display apparatus according to the embodiment of the present disclosure, the upper surface of the first lens insulating layer 621 formed on each emission area R-EA, G-EA and B-EA can have a concave shape toward the device substrate 100.

As shown in FIGS. 4 and 5, the method of forming the display apparatus according to the embodiment of the present disclosure can include a step of forming the second lens insulating layer 622 on the first lens insulating layer 621 on each emission area R-EA, G-EA and B-EA, a step of forming the lens passivation layer 623 on the second lens insulating layer 622 on each emission area R-EA, G-EA and B-EA, a step of forming the color filters 500R, 500G and 500B on the device substrate 100 in which the lens passivation layer 623 of each emission area R-EA, G-EA and B-EA is formed, and a step of forming the filter passivation layer 700 on the color filters 500R, 500G and 500B.

The second lens insulating layer 622 of each emission area R-EA, G-EA and B-EA can be formed by a same process as the first lens insulating layer 621 of each emission area R-EA, G-EA and B-EA. For example, the step of forming the second lens insulating layer 622 on each emission area R-EA, G-EA and B-EA can include a step of forming a second preliminary insulating layer on the first lens insulating layer 621 of each emission area R-EA, G-EA and B-EA, and a step of curing the second preliminary insulating layer of each emission area R-EA, G-EA and B-EA. The step of forming the second preliminary insulating layer on each emission area R-EA, G-EA and B-EA can include a coating process. The step of curing the second preliminary insulating layer of each emission area R-EA, G-EA and B-EA can include a drying process. Thus, in the method of forming the display apparatus according to the embodiment of the present disclosure, the boundary between the first lens insulating layer 621 and the second lens insulating layer 622 on each emission area R-EA, G-EA and B-EA can be formed to have a same shape as the boundary between the first lens insulating layer 621 and the second lens insulating layer 622 on adjacent emission area R-EA, G-EA and B-EA.

The second preliminary insulating layer can be formed of an insulating material. The second preliminary insulating layer can be formed of a transparent material. For example, the second preliminary insulating layer can be formed of an organic insulating material. The second preliminary insulating layer can be formed of a material having a refractive index larger than the first preliminary insulating layer 621a. For example, the second preliminary insulating layer can be formed of a different material from the first preliminary insulating layer 621a. Thus, in the method of forming the display apparatus according to the embodiment of the present disclosure, the light passing through the first lens insulating layer 621 of each emission area R-EA, G-EA and B-EA can be refracted at the boundary between the first lens insulating layer 621 and the second lens insulating layer 622 on the corresponding emission area R-EA, G-EA and B-EA due to the difference in refractive index of the first lens insulating layer 621 and the second lens insulating layer 622 on the corresponding emission area R-EA, G-EA and B-EA. For example, in the method of forming the display apparatus according to the embodiment of the present disclosure, the boundary between the first lens insulating layer 621 and the second lens insulating layer 622 on each emission area R-EA, G-EA and B-EA can function as a lens concentrating light. The light emitted from the light-emitting device 300 of each emission area R-EA, G-EA and B-EA can be primarily concentrated at the boundary between the first lens insulating layer 621 and the second lens insulating layer 622 in the corresponding emission area R-EA, G-EA and B-EA. That is, in the method of forming the display apparatus according to the embodiment of the present disclosure, process efficiency can be improved.

A vertical distance between the device substrate 100 and the upper surface of the second lens insulating layer 622 opposite to the encapsulation structure 400 on each emission area R-EA, G-EA and B-EA can gradually increase from the central area of the corresponding emission area R-EA, G-EA and B-EA toward the barrier 610. For example, the upper surface of the second lens insulating layer 622 formed on each emission area R-EA, G-EA and B-EA can have a concave shape toward the device substrate 100. The upper surface of the second lens insulating layer 622 on each emission area R-EA, G-EA and B-EA can be formed to have a same shape as the upper surface of the first lens insulating layer 621 on the corresponding emission area R-EA, G-EA and B-EA. For example, the upper surface of the second lens insulating layer 622 on each emission area R-EA, G-EA and B-EA can have a same curvature as the upper surface of the first lens insulating layer 621 on the corresponding emission area R-EA, G-EA and B-EA. The upper surface of the second lens insulating layer 622 on each emission area R-EA, G-EA and B-EA can be formed to have a same shape as the upper surface of the second lens insulating layer 622 on adjacent emission area R-EA, G-EA and B-EA.

The lens passivation layer 623 of each emission area R-EA, G-EA and B-EA can be formed of an insulating material. The lens passivation layer 623 of each emission area R-EA, G-EA and B-EA can be formed of a transparent material. The lens passivation layer 623 of each emission area R-EA, G-EA and B-EA can be formed of a material having a refractive index larger than the second preliminary insulating layer. Thus, in the method of forming the display apparatus according to the embodiment of the present disclosure, the light passing through the second lens insulating layer 622 of each emission area R-EA, G-EA and B-EA can be refracted at the boundary between the second lens insulating layer 622 and the lens passivation layer 623 on the corresponding emission area R-EA, G-EA and B-EA due to the differences in refractive index of the second lens insulating layer 622 and the lens passivation layer 623 on the corresponding emission area R-EA, G-EA and B-EA. For example, in the method of forming the display apparatus according to the embodiment of the present disclosure, the boundary between the second lens insulating layer 622 and the lens passivation layer 623 on each emission area R-EA, G-EA and B-EA can function as a lens concentrating light. That is, in the method of forming the display apparatus according to the embodiment of the present disclosure, the light emitted from the light-emitting device 300 of each emission area R-EA, G-EA and B-EA can be primarily concentrated at the boundary between the first lens insulating layer 621 and the second lens insulating layer 622 on the corresponding emission area R-EA, G-EA and B-EA, and can be secondarily concentrated at the boundary between the second lens insulating layer 622 and the lens passivation layer 623 on the corresponding emission area R-EA, G-EA and B-EA. Therefore, in the method of forming the display apparatus according to the embodiment of the present disclosure, the concentration efficiency of each emission area R-EA, G-EA and B-EA can be improved.

The first lens insulating layer 621, the second lens insulating layer 622 and the lens passivation layer 623 on each emission area R-EA, G-EA and B-EA can constitute the lens structure 620 disposed on the corresponding emission area R-EA, G-EA and B-EA. For example, the side of the lens structure 620 on each emission area R-EA, G-EA and B-EA can be in direct contact with the barrier 610. The lens passivation layer 623 of each emission area R-EA, G-EA and B-EA can be formed of a different material from the second lens insulating layer 622 of the corresponding emission area R-EA, G-EA and B-EA. The lens passivation layer 623 of each emission area R-EA, G-EA and B-EA can be formed of a material harder than the second lens insulating layer 622 of the corresponding emission area R-EA, G-EA and B-EA. For example, the lens passivation layer 623 of each emission area R-EA, G-EA and B-EA can be formed of an inorganic insulating material, such as silicon oxide (SiOx) and silicon nitride (SiNx). Thus, in the method of forming the display apparatus according to the embodiment of the present disclosure, the boundary between the first lens insulating layer 621 and the second lens insulating layer 622 and the boundary between the second lens insulating layer 622 and the lens passivation layer 623 on each emission area R-EA, G-EA and B-EA can not be deformed by the external impact. That is, in the method of forming the display apparatus according to the embodiment of the present disclosure, the concentration efficiency of the lens structure 620 on each emission area R-EA, G-EA and B-EA can be kept the same. Therefore, in the method of forming the display apparatus according to the embodiment of the present disclosure, the luminance deviation due to the differences in the concentration efficiency of the emission areas R-EA, G-EA and B-EA can be prevented.

Accordingly, the method of forming the display apparatus according to the embodiment of the present disclosure can include the step of forming the barrier 610 on the encapsulation structure 400, and the step of forming the lens structure 620 on the encapsulation structure 400 of each emission area R-EA, G-EA and B-EA exposed by the barrier 610, wherein the lens structure 620 of each emission area R-EA, G-EA and B-EA can include at least two boundary formed by a coating process and a curing process, wherein the boundaries within each lens structure 620 can be formed to have a concave shape toward the device substrate 100. Thus, in the method of forming the display apparatus according to the embodiment of the present disclosure, a process of forming the lens structure 620 on each emission area R-EA, G-EA and B-EA to the concentration of the light emitted from the light-emitting device 300 of the corresponding emission area R-EA, G-EA and B-EA can be simplified. The light emitted from the light-emitting device 300 of each emission area R-EA, G-EA and B-EA toward the color filter 500R, 500G and 500B of adjacent emission area R-EA, G-EA and B-EA can be reflected toward the central area of the corresponding emission area R-EA, G-EA and B-EA by the barrier 610. Therefore, in the method of forming the display apparatus according to the embodiment of the present disclosure, the efficiency of concentrating the light emitted from each light-emitting device 300 can be improved, without decreasing the process efficiency. And, in the method of forming the display apparatus according to the embodiment of the present disclosure, uniformity of the lens structure 620 can be improved.

The display apparatus according to the embodiment of the present disclosure is described that the driving circuit DC of each sub-pixel SP consists of the first thin film transistor TR1, the second thin film transistor TR2 and the storage capacitor Cst. However, in the display apparatus according to another embodiment of the present disclosure, the driving circuit DC of each sub-pixel SP can include a driving thin film transistor and at least one switching thin film transistor. For example, in the display apparatus according to another embodiment of the present disclosure, the driving circuit DC of each sub-pixel SP can further include a third thin film transistor for initializing the storage capacitor Cst of the corresponding sub-pixel SP according to the gate signal. The third thin film transistor of each sub-pixel SP can include a third well region, a third drain region, a third source region, a third gate electrode, a third drain electrode and a third source electrode. The third well region, the third drain region and the third source region can be formed in the device substrate 100. The third gate electrode of each sub-pixel SP can be electrically connected to the corresponding gate line GL, the third drain electrode of each sub-pixel SP can be electrically connected to an initial line applying an initial signal, and the third source electrode of each sub-pixel SP can be electrically connected to the storage capacitor Cst of the corresponding sub-pixel SP. Thus, in the display apparatus according to another embodiment of the present disclosure, the degree of freedom in configuration of each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the first well, the second drain region 102d and the second source region 102s of each sub-pixel SP can include P-type impurities, and the first drain region, the first source region and the second well region 102w of each sub-pixel SP can include N-type impurities. However, in the display apparatus according to another embodiment of the present disclosure, the second well region 102w of each sub-pixel SP can include conductive impurities same as the first well region of the corresponding sub-pixel SP. For example, in the display apparatus according to another embodiment of the present disclosure, the first well region and the second well region 102w of each sub-pixel SP can include P-type impurities. The first drain region, the first source region, the second drain region 102d and the second source region 102s of each sub-pixel SP can include N-type impurities. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the device substrate 100 can be a wafer formed of a semiconductor material, such as silicon. However, in the display apparatus according to another embodiment of the present disclosure, the device substrate 100 can include glass or plastic. In the display apparatus according to another embodiment of the present disclosure, the driving circuit DC of each sub-pixel SP can be formed on the upper surface of the device substrate 100. For example, in the display apparatus according to another embodiment of the present disclosure, a buffer layer including an inorganic insulating layer, such as silicon oxide (SiOx) and silicon nitride (SiNx), can be formed on the upper surface of the device substrate 100, and the first thin film transistor TR1 and the second thin film transistor TR2 of each sub-pixel SP can include a semiconductor pattern formed on the buffer layer. The semiconductor pattern can include a semiconductor material. For example, a first semiconductor pattern of the first thin film transistor TR1 and a second semiconductor pattern of the second thin film transistor TR2 in each sub-pixel SP can include an oxide semiconductor, such as IGZO. Thus, in the display apparatus according to another embodiment of the present disclosure, the degree of freedom in the material of the device substrate 100 and the configuration of each driving circuit DC can be improved.

The display apparatus according to the embodiment of the present disclosure is described that the first electrode 310 of each sub-pixel SP can have a relative larger reflectance. However, in the display apparatus according to another embodiment of the present disclosure, the first electrode 310 of each sub-pixel SP can be a transparent electrode having a high transmittance, and a reflective electrode can be disposed between the device substrate 100 and the first electrode 310 of each sub-pixel SP. For example, the first electrode 310 of each sub-pixel SP can be made of a transparent conductive material, such as ITO and IZO. A distance between the reflective electrode and the first electrode 310 in each sub-pixel SP can be determined by a color realized in the emission area R-EA, G-EA and B-EA of the corresponding sub-pixel SP. For example, a distance between the reflective electrode and the first electrode 310 in the red emission area R-EA can be different from a distance between the reflective electrode and the first electrode 310 in the green emission area G-EA and a distance between the reflective electrode and the first electrode 310 in the blue emission area B-EA. That is, in the display apparatus according to another embodiment of the present disclosure, light having a wavelength range corresponding to a color realized by each emission area R-EA, G-EA and B-EA can resonate between the reflective electrode and the second electrode 330 of the corresponding emission area R-EA, G-EA and B-EA. Therefore, in the display apparatus according to another embodiment of the present disclosure, the concentration efficiency and the color gamut of each emission area R-EA, G-EA and B-EA can be improved.

The display apparatus according to the embodiment of the present disclosure is described that the barrier 610 can include a material having a relative high reflectance. However, in the display device according to another embodiment of the present disclosure, the light emitted from the light-emitting device 300 of each emission area R-EA, G-EA and B-EA to the color filter 500R, 500G and 500B of adjacent emission area R-EA, G-EA and B-EA can be reflected due to the difference in the refractive index between the barrier 610 and the lens structure 620 of the corresponding emission area R-EA, G-EA and B-EA. For example, in the display device according to another embodiment of the present disclosure, the barrier 610 can include a material having smaller refractive index than the lens structure 620 of each emission area R-EA, G-EA and B-EA. The barrier 610 can include an insulating material. Thus, in the display apparatus according to another embodiment of the present disclosure, the degree of freedom in the material of the barrier 610 and a process of forming the barrier 610 can be improved.

The display apparatus according to the embodiment of the present disclosure is described that the color filter 500R, 500G and 500B of each emission area R-EA, G-EA and B-EA can have the refractive index smaller than the lens passivation layer of the corresponding emission area R-EA, G-EA and B-EA. However, in the display device according to another embodiment of the present disclosure, the color filter 500R, 500G and 500B of each emission area R-EA, G-EA and B-EA can have the refractive index larger than the lens passivation layer of the corresponding emission area R-EA, G-EA and B-EA. Thus, in the display apparatus according to another embodiment of the present disclosure, the image with a narrow viewing angle can be realized. For example, in the display apparatus according to another embodiment of the present disclosure, the image provided to the user can not be recognized by people disposed around the user. And, in the display apparatus according to another embodiment of the present disclosure, the light emitted from the light-emitting device 300 of each emission area R-EA, G-EA and B-EA can be concentrated at the boundary between the first lens insulating layer 621 and the second lens insulating layer 622 on the corresponding emission area R-EA, G-EA and B-EA, the boundary between the second lens insulating layer 622 and the lens passivation layer 623 on the corresponding emission area R-EA, G-EA and B-EA, and the boundary between the lens passivation layer 623 and the color filter 500R, 500G and 500B on the corresponding emission area R-EA, G-EA and B-EA. Therefore, in the display apparatus according to another embodiment of the present disclosure, the concentration efficiency and the frontal luminance of each emission area R-EA, G-EA and B-EA can be greatly improved.

The display apparatus according to the embodiment of the present disclosure is described that the lens structure 620 of each emission area R-EA, G-EA and B-EA can have a stacked structure of the first lens insulating layer 621, the second lens insulating layer 622 and the lens passivation layer 623. However, in the display device according to another embodiment of the present disclosure, the lens structure 620 of each emission area R-EA, G-EA and B-EA can include at least three lens insulating layers 621 and 622 disposed between the encapsulation structure 400 and the lens passivation layer 623 of the corresponding emission area R-EA, G-EA and B-EA. For example, in the display apparatus according to another embodiment of the present disclosure, at least three boundaries can be disposed in the lens structure 620 of each emission area R-EA, G-EA and B-EA. Each of the boundaries disposed in each lens structure 620 can have a convex shape toward the device substrate 100. The lens insulating layers 621 and 622 disposed between the encapsulation structure 400 and the lens passivation layer 623 of each emission area R-EA, G-EA and B-EA can have a refractive index, which increases as they become farther away from the encapsulation structure 400. The lens passivation layer 623 of each emission area R-EA, G-EA and B-EA can have a relative larger refractive index than the lens insulating layer 621 and 622 of the corresponding emission area R-EA, G-EA and B-EA. Thus, in the display apparatus according to another embodiment of the present disclosure, the concentration efficiency by the lens structure 620 in each emission area R-EA, G-EA and B-EA can be effectively improved.

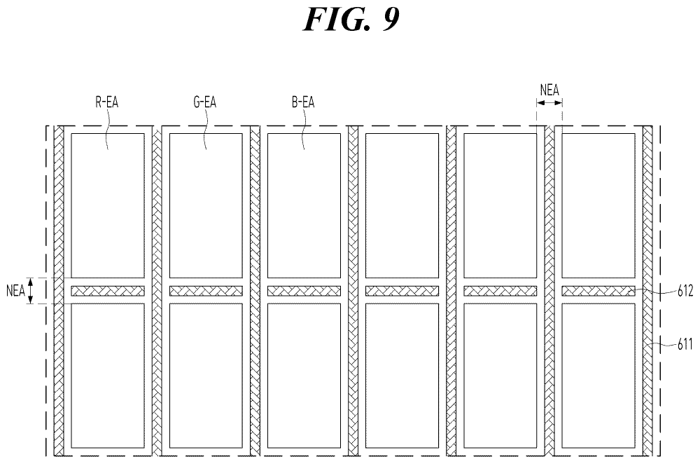

The display apparatus according to the embodiment of the present disclosure is described that the plane of the barrier 610 can have a mesh shape. However, in the display device according to another embodiment of the present disclosure, a portion of the barrier 610 can be separated from other portions of the barrier 610. For example, in the display apparatus according to another embodiment of the present disclosure, the second barrier region 612 extending in the second direction can be spaced apart from the first barrier region 611 extending in the first direction, as shown in FIG. 9. Thus, in the display apparatus according to another embodiment of the present disclosure, the lens structure 620 of each emission area R-EA, G-EA and B-EA can partially contact with the lens passivation layer 630 of adjacent emission area R-EA, G-EA and B-EA. Therefore, in the display apparatus according to another embodiment of the present disclosure, the spreadability of the first preliminary insulating layer 621a and the spreadability of the second preliminary insulating layer, which are deposited on each emission area R-EA, G-EA and B-EA can be improved. In the display apparatus according to another embodiment of the present disclosure, uniformity of the boundaries disposed in the lens structure 620 of each emission area R-EA, G-EA and B-EA can be improved.

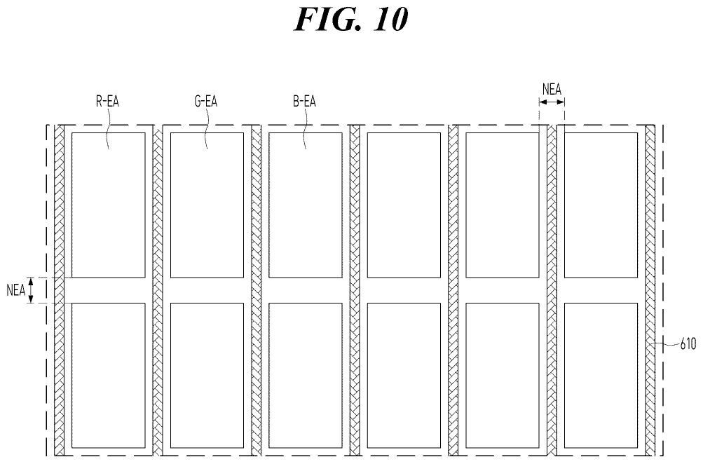

The display apparatus according to the embodiment of the present disclosure is described that the barrier 610 can include the first barrier region 611 extending in the first direction and the second barrier region 612 extending in the second direction. However, in the display apparatus according to another embodiment of the present disclosure, the barrier 610 can extend only in a single direction. For example, in the display apparatus according to another embodiment of the present disclosure, the barrier 610 can be disposed only between the emission areas R-EA, G-EA and B-EA, which display different colors, as shown in FIG. 10. The barrier 610 can not be disposed between the emission areas R-EA, G-EA and B-EA, which display the same color. Thus, in the display apparatus according to another embodiment of the present disclosure, the spreadability of the first preliminary insulating layer 621a and the second preliminary insulating layer deposited on each emission area R-EA, G-EA and B-EA can be effectively improved. Therefore, in the display apparatus according to another embodiment of the present disclosure, uniformity of the boundaries disposed within the lens structure 620 of each emission area R-EA, G-EA and B-EA can be effectively improved.

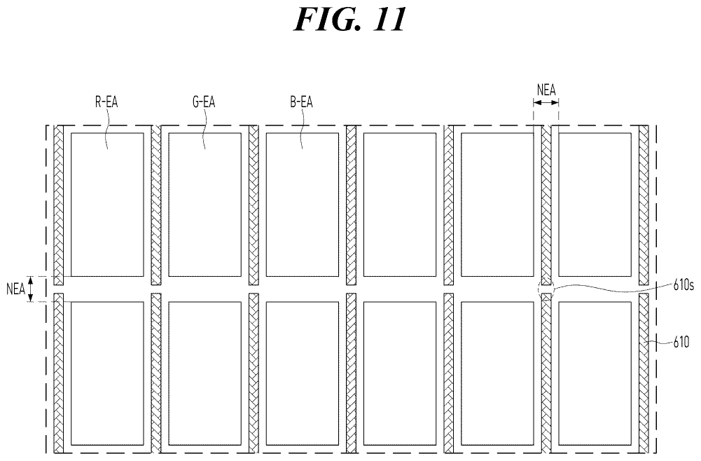

In the display apparatus according to another embodiment of the present disclosure, the first preliminary insulating layer 621a and the second preliminary insulating layer deposited on each emission area R-EA, G-EA and B-EA can have improved spreadability in the first direction and the second direction. For example, in the display apparatus according to another embodiment of the present disclosure, the barrier 610 can extend only in the first direction between the emission areas R-EA, G-EA and B-EA, and the barrier 610 can include at least one slit (610s), as shown in FIG. 11. The slit 610s can be disposed between the emission areas R-EA, G-EA and B-EA adjacent in the first direction. Thus, in the display apparatus according to another embodiment of the present disclosure, the spreadability of the first preliminary insulating layer 621a and the second preliminary insulating layer deposited on each emission area R-EA, G-EA and B-EA can be improved, and a decrease in the concentration efficiency of each emission area R-EA, G-EA and B-EA due to flow of the first preliminary insulating layer 621a and/or flow of the second preliminary insulating layer can be prevented.

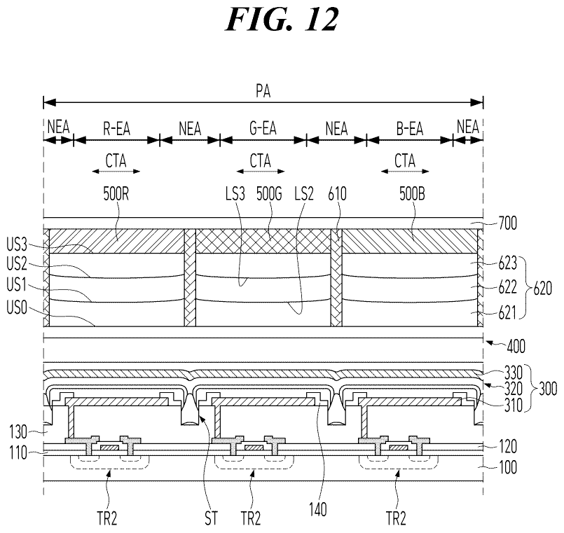

The display apparatus according to the embodiment of the present disclosure is described that the boundary between adjacent color filters 500R, 500G and 500B can overlap the barrier 610. However, in the display apparatus according to another embodiment of the present disclosure, the color filter 500R, 500G and 500B of each emission area R-EA, G-EA and B-EA can be formed on the lens passivation layer 623 only in the corresponding emission area R-EA, G-EA and B-EA. For example, in the display apparatus according to another embodiment of the present disclosure, the barrier 610 can extend between the color filters 500R, 500G and 500B, as shown in FIG. 12. An upper end portion of the barrier 610 opposite to the device substrate 100 can be in direct contact with the filter passivation layer 700. The color filter 500R, 500G and 500B of each emission area R-EA, G-EA and B-EA can be formed within a region defined by the barrier 610. Thus, in the display apparatus according to another embodiment of the present disclosure, the degree of freedom in the material of the color filters 500R, 500G and 500B and a process of forming the color filters 500R, 500G and 500B can be improved. And, in the display apparatus according to another embodiment of the present disclosure, color mixing can be effectively prevented.

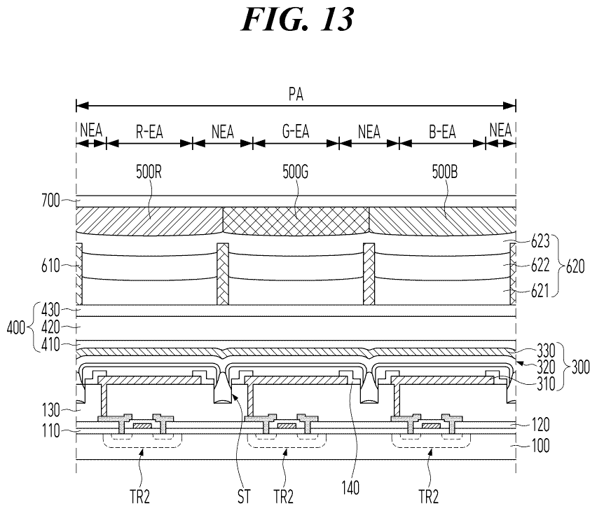

The display apparatus according to the embodiment of the present disclosure is described that the boundary between the lens passivation layer 623 and the color filter 500R, 500G and 500B on each emission area R-EA, G-EA and B-EA can be a flat surface. However, in the display apparatus according to another embodiment of the present disclosure, the boundary between the lens passivation layer 623 and the color filter 500R, 500G and 500B on each emission area R-EA, G-EA and B-EA can have various shapes. For example, in the display apparatus according to another embodiment of the present disclosure, the boundary between the lens passivation layer 623 and the color filter 500R, 500G and 500B on each emission area R-EA, G-EA and B-EA can have a convex shape toward the device substrate 100, as shown in FIG. 13. An upper surface of the lens passivation layer 623 of each emission area R-EA, G-EA and B-EA toward the corresponding color filter 500R, 500G and 500B can have a concave shape toward the device substrate 100. For example, the upper surface of the lens passivation layer 623 on each emission area R-EA, G-EA and B-EA can have a same curvature as the upper surface of the second lens insulating layer 622 on the corresponding emission area R-EA, G-EA and B-EA. The upper surface of the lens passivation layer 623 on each emission area R-EA, G-EA and B-EA can have a same shape as the upper surface of the second lens insulating layer 622 on the corresponding emission area R-EA, G-EA and B-EA. Thus, in the display apparatus according to another embodiment of the present disclosure, the concentration efficiency and the viewing angle characteristics can be effectively improved due to the boundary between the lens passivation layer 623 and the color filter 500R, 500G and 500B on each emission area R-EA, G-EA and B-EA.

The lens passivation layer 623 of each emission area R-EA, G-EA and B-EA can be in direct contact with the lens passivation layer 623 of adjacent emission area R-EA, G-EA and B-EA. For example, an upper end portion of the barrier 610 opposite to the encapsulation structure 400 can be spaced apart from the color filters 500R, 500G and 500B. The lens passivation layer 623 of each emission area R-EA, G-EA and B-EA can extend between the barrier 610 and the color filters 500R, 500G and 500B. For example, the upper end portion of the barrier 610 can be covered by the lens passivation layer 623. Thus, in the display apparatus according to another embodiment of the present disclosure, the damage of the color filters 500R, 500G and 500B due to the barrier 610 can be prevented. And, in the display apparatus according to the another embodiment of the present disclosure, the upper surface of the lens passivation layer 623 having a curved shape on each emission area R-EA, G-EA and B-EA can be effectively formed. Therefore, in the display apparatus according to another embodiment of the present disclosure, the concentration efficiency and the luminance of each emission area R-EA, G-A and BEA can be improved, without complicated processes.

In the result, the display apparatus according to the embodiments of the present disclosure can comprise the lens structure disposed between the encapsulation structure covering the light-emitting device and the color filter, and the barrier contacting the side of the lens structure, wherein the lens structure can have a structure in which at least three layers are stacked, wherein each layer of the lens structure can have the refractive index that increases with distance from the encapsulation structure, and wherein the boundaries between the layers within the lens structure can have a convex shape toward the light-emitting device. Thus, in the display apparatus according to the embodiments of the present disclosure, the concentration efficiency of the light emitted from the light-emitting device can be improved, without complicated processes. And, in the display apparatus according to the embodiments of the present disclosure, the uniformity of the lens structure can be improved. That is, in the display apparatus according to the embodiments of the present disclosure, the concentration efficiency of each emission area can be improved, and the luminance deviation due to the concentration efficiency of the emission areas can be prevented. Thereby, in the display apparatus according to the embodiments of the present disclosure, the quality of the image can be improved. Further, in the display apparatus according to the embodiments of the present disclosure, low-power driving can be possible, and power consumption can be reduced.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a light-emitting device disposed on an emission area of a device substrate;
an encapsulation structure disposed on the device substrate, the encapsulation structure on the light-emitting device;
a lens structure including a first lens insulating layer, a second lens insulating layer, and a lens passivation layer, which are sequentially stacked on the encapsulation structure of the emission area;
a barrier disposed on the encapsulation structure, the barrier being in contact with a side of the lens structure; and
a color filter disposed on the lens structure, the color filter overlapping with the emission area,
wherein the second lens insulating layer has a larger refractive index than the first lens insulating layer,
wherein the lens passivation layer has a larger refractive index than the second lens insulating layer, and
wherein an upper surface of the first lens insulating layer and an upper surface of the second lens insulating layer toward the color filter have a concave shape toward the device substrate.

2. The display apparatus according to claim 1, wherein the upper surface of the second lens insulating layer has a same curvature as the upper surface of the first lens insulating layer.

3. The display apparatus according to claim 1, wherein the barrier includes a material having a larger reflectance than the first lens insulating layer, the second lens insulating layer, and the lens passivation layer.

4. The display apparatus according to claim 3, wherein the barrier includes a metal.

5. The display apparatus according to claim 3, wherein the lens passivation layer includes a material harder than the first lens insulating layer and the second lens insulating layer.

6. The display apparatus according to claim 5, wherein the first lens insulating layer and the second lens insulating layer includes an organic insulating material and the lens passivation layer includes an inorganic insulating material.

7. The display apparatus according to claim 1, wherein an upper surface of lens passivation layer toward the color filter has a concave shape toward the device substrate.

8. The display apparatus according to claim 7, wherein an upper end of the barrier toward the color filter is spaced apart from the color filter and the lens passivation layer extends between the upper end of the barrier and the color filter.

9. The display apparatus according to claim 7, wherein the refractive index of the color filter is larger than the refractive index of the lens passivation layer.

10. The display apparatus according to claim 7, wherein the refractive index of the color filter is smaller than the refractive index of the lens passivation layer.

11. The display apparatus according to claim 7, wherein the upper surface of the lens passivation layer has a same curvature as the upper surface of the second lens insulating layer.

12. The display apparatus according to claim 1, wherein a thickness of the first lens insulating layer disposed in each emission area gradually increases from a central area of the corresponding emission area toward the barrier.

13. The display apparatus according to claim 1, wherein a boundary between the first lens insulating layer and the second lens insulating layer disposed in each emission area functions as a lens.

14. The display apparatus according to claim 1, wherein a boundary between the second lens insulating layer and the lens passivation layer disposed in each emission area functions as a lens.

15. A display apparatus comprising:
a first light-emitting device disposed on a first emission area of a device substrate;
an encapsulation structure disposed on the first light-emitting device, the encapsulation structure extending outward of the first emission area;
a first lens structure including at least three layers stacked on the encapsulation structure of the first emission area;
a first barrier disposed on the encapsulation structure, the first barrier being in contact with a side of the first lens structure; and
a first color filter disposed on the first lens structure, the first color filter overlapping with the first emission area from a plan view,
wherein each layer of the first lens structure has a larger refractive index as it moves away from the encapsulation structure, and
wherein each of boundaries between the layers within the first lens structure has a convex shape toward the device substrate.

16. The display apparatus according to claim 15, wherein a vertical distance between the device substrate and each boundary increases from a central area of the first emission area to the first barrier.

17. The display apparatus according to claim 15, further comprising:
a second light-emitting device disposed between a second emission area of the device substrate and the encapsulation structure;
a second lens structure including at least three layers stacked on the encapsulation structure of the second emission area;
a second barrier disposed on the encapsulation structure, the second barrier being in contact with a side of the second lens structure; and
a second color filter disposed on the second lens structure, the second color filter overlapping with the second emission area from a plan view,
wherein the first barrier and the second barrier extend in a first direction,
wherein the second emission area is disposed side by side with the first emission area in the first direction, and
wherein the second color filter includes a same material as the first color filter.

18. The display apparatus according to claim 17, wherein the second barrier is spaced apart from the first barrier between the first emission area and the second emission area.

19. The display apparatus according to claim 17, further comprising a third barrier disposed between the first emission area and the second emission area, the third barrier extending in a second direction perpendicular to the first direction.

20. The display apparatus according to claim 15, further comprising:
a third light-emitting device disposed between a third emission area of the device substrate and the encapsulation structure;
a third lens structure including at least three layers stacked on the encapsulation structure of the third emission area;
a fourth barrier disposed on the encapsulation structure, the fourth barrier being in contact with a side of the third lens structure; and
a third color filter disposed on the third lens structure, the third color filter overlapping with the third emission area,
wherein each layer of the third lens structure has a larger refractive index as it moves away from the encapsulation structure, and
wherein each of boundaries between the layers within the third lens structure has a convex shape toward the device substrate.

21. A display apparatus comprising:
a light-emitting device disposed on a plurality of emission areas of a device substrate;
an encapsulation structure disposed on the device substrate, the encapsulation structure covering the light-emitting device;
a plurality of lens structures each of which including a plurality of layers stacked on the encapsulation structure of the plurality of emission areas; and
a plurality of color filters disposed on the plurality of lens structures, each of the plurality of color filters overlapping with each of the plurality of emission areas,
wherein each layer of each of the plurality of lens structures has a larger refractive index as it moves away from the encapsulation structure, and
wherein each of boundaries between the layers within each of the plurality of lens structures has a convex shape toward the device substrate.
